(19) United States
(12) Patent Application Publication
(10) Pub. No.: US 2013/0256608 A1
(43) Pub. Date: Oct. 3, 2013

(54) METAL MATERIAL HAVING n-TYPE THERMOELECTRIC CONVERSION CAPABILITY

(71) Applicants: Ryoji Funahashi, Ikeda-shi (JP); Hideaki Tanaka, Ikeda-shi (JP); Tomonari Takeuchi, Ikeda-shi (JP); Tetsuo Nomura, Ikeda-shi (JP)

(72) Inventors: Ryoji Funahashi, Ikeda-shi (JP); Hideaki Tanaka, Ikeda-shi (JP); Tomonari Takeuchi, Ikeda-shi (JP); Tetsuo Nomura, Ikeda-shi (JP)

(73) Assignees: NATIONAL INSTITUTE OF ADVANCED INDUSTRIAL SCIENCE AND TECHNOLOGY, Tokyo (JP); TES NEWENERGY CO., Ikeda-shi, Osaka (JP)

(21) Appl. No.: 13/992,501

(22) PCT Filed: Dec. 1, 2011
(86) PCT No.: PCT/JP2011/077852

§ 371 Date: Jun. 7, 2013

(30) Foreign Application Priority Data
Dec. 7, 2010 (JP) 2010-272204

(51) Int. Cl. H01L 35/20

(52) U.S. Cl. CPC H01L 35/20
USPC 252/519.12; 423/324; 252/519.1; 252/519.14; 423/299; 423/276; 252/519.13

(57) ABSTRACT

The present invention provides a metal material comprising an alloy that is represented by the compositional formula Mn₃₋ₓM¹ₓSi_{y}Al_{z}M²ₐ, wherein M¹ is at least one element selected from the group consisting of Ti, V, Cr, We, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a≦1, the alloy having a negative Seebeck coefficient and an electrical resistivity of 1 mΩ·cm or less at a temperature of 25° C. or higher. The metal material of the present invention is a novel material that has good thermoelectric conversion capability in the intermediate temperature region and excellent durability, and that is useful as an n-type thermoelectric conversion material.

### TECHNICAL FIELD

The present invention relates a novel metal material having excellent performance as an n-type thermoelectric conversion material.

### BACKGROUND ART

In Japan, the yield of effective energy obtained from the primary supply energy is only about 30%, and about 70% of the energy is eventually discarded as heat into the atmosphere. In addition, the heat generated by combustion in factories, garbage incineration plants, and the like is also released into the atmosphere without being converted to other energy. In this manner, we, humankind, are wastefully discarding an enormous amount of heat energy and are obtaining only a small amount of energy from action such as combustion of fossil energy.

In order to increase the yield of energy, it is effective to enable utilization of the heat energy released into the atmosphere. For that purpose, thermoelectric conversion of directly converting heat energy to electrical energy is an effective means. The thermoelectric conversion utilizes the Seebeck effect and is an energy conversion method for generating electricity by making a difference in temperature between both ends of a thermoelectric conversion material to produce a difference in electrical potential. In this method, electricity is obtained merely by placing one end of the thermoelectric conversion material at a portion heated to a high temperature by waste heat, placing the other end thereof in the atmosphere (room temperature), and connecting a conducting wire to both ends thereof. This method does not require any mobile equipment such as a motor or a turbine required for general electricity generation. Thus, the cost of this method is low, and the method allows electricity to be continuously generated without emitting gas by combustion and the like, until the thermoelectric conversion material is degraded.

As described above, thermoelectric generation is expected as a technology that plays a part in the resolution of energy problems that will be concerned hereafter. However, to realize the thermoelectric generation, there is a need for a thermoelectric conversion material having a high thermoelectric conversion efficiency and high durability. In particular, it is important that a thermoelectric conversion material does not become oxidized in air at a usage temperature.

Hitherto, CoO₂-based layered oxides such as Ca₃Co₄O₉ have been reported as materials exhibiting excellent thermoelectric performance in the air at a high temperature (see Non-patent Literature 1 below). However, these oxides exhibit high conversion efficiencies at a temperature of 600° C. or higher but exhibit, low conversion efficiencies in an intermediate temperature range of about 200° C. to 600° C.

With regard to materials exhibiting favorable thermoelectric conversion performance in the intermediate temperature range, MnSi_{1.7} has been known as a p-type thermoelectric conversion material to be relatively resistant to oxidation in the intermediate temperature range and exhibit favor-aisle thermoelectric properties (see Patent Literature 1 below).

However, with regard to n-type thermoelectric conversion materials, intermetallic compounds such as Mg₂Si, Skutterudite, and Half-Heusler exhibit, favorable thermoelectric conversion performance in the intermediate temperature range. However, these intermetallic compounds cause oxidation in air at a temperature of higher than 300° C. Thus, these intermetallic compounds have insufficient durability and cannot be used for a long period of time.

### CITATION LIST

### Patent Literature

PTL 1: JP42-8128B

### Non-Patent Literature

NPL 1: R. Funahashi et al., Jpn. J. Appl. Phys., 39, L1127 (2000)

### SUMMARY OF INVENTION

### Technical Problem

The present invention has been made in view of the aforementioned problems of the prior art techniques. A main object of the present invention is to provide a novel material usable as an n-type thermoelectric conversion material that has satisfactory thermoelectric conversion capability in the intermediate temperature region, and excellent durability in the air.

### Solution to Problem

The present inventors conducted extensive research, and found that a metal material comprising an alloy containing Si and Al as essential components and further containing specific elements at. a specific ratio has a negative Seebeck coefficient and exhibits excellent electrical conductivity. They further found that the metal material has excellent thermoelectric conversion capability in the air, even in the intermediate temperature region; i.e., from room temperature to about 600° C., the metal material exhibits excellent oxidation resistance and desirable durability in this temperature region. The present invention has been accomplished based on the above findings.

More specifically, the present invention provides a metal material, and an n-type thermoelectric conversion material using the metal material.

1. A metal material comprising an alloy represented by compositional formula: Mn₃₋ₓM¹ₓSi_{y}Al_{z}M²ₐ,

wherein M¹ is at least one element selected from the group consisting of Ti, V, Cr, Fe, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a≦1,

the alloy having a negative Seebeck coefficient at a temperature of 25° C. or higher.

2. A metal material comprising an alloy represented by compositional formula: Mn₃₋ₓM¹ₓSi_{y}Al_{z}M²ₐ,

wherein M¹ is at least one element, selected from the group consisting of Ti, V, Cr, Fe, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a≦1,

the alloy having an electrical resistivity of 1 mΩ·cm or less at a temperature of 25° C. or higher.

3. An n-type thermoelectric conversion material comprising the metal material of Item 1 or 2 or a sintered body thereof.

4. A thermoelectric conversion module comprising the n-type thermoelectric conversion material of Item 3.

The metal material of the present invention is represented by compositional formula: Mn₃₋ₓM¹ₓSi_{y}Al_{z}M²ₐ, wherein M¹ is at least one element selected from the group consisting of Ti, V, Cr, Fe, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a≦1.

The metal material is not a mere mixture of components; rather, it is in the state of an alloy in which each element is closely related and uniformly present in the entire of the material.

The metal material comprising an alloy represented by the compositional formula shown above has a negative Seebeck coefficient. Mien the body formed of the metal material is given a temperature difference between one end and the other end, the electric potential generated by the thermoelectromotive force becomes such that the hot side has a higher electric potential and the cold side has a lower electric potential, thus exhibiting the characteristics as an n-type thermoelectric conversion material. More specifically, the metal material has a negative Seebeck coefficient in the temperature range of about 25 to 700° C.

The metal material has excellent electrical conductivity and low electric resistivity; for example, it exhibits a very low electric resistivity of 1 mΩ·cm or less in the temperature range of 25 to 700° C. Furthermore, the metal material has excellent durability, even under an oxidizing atmosphere such as in the air; for example, it is almost, free from deterioration in thermoelectric conversion capability, even when used for a long period of time in the temperature range of about 25 to 700° C. in the air.

There is no particular limitation to the method for producing the metal material of the present invention. In one example, the raw materials are mixed in such a manner that the element ratio thereof becomes the same as that of the target alloy, after which the raw material mixture is melted under a high temperature, and then cooled. Examples of usable raw materials include, in addition to elementary metals, intermetallic compounds and solid solutions comprising a plurality of constituent elements, and composites thereof (such as alloys). There is no particular limitation to the method for melting the raw materials; for example, the raw materials may be heated to a temperature exceeding the melting point of the raw material phase or product phase by arc melting or other methods. In order to prevent the oxidation of the raw materials, the melting is preferably performed under a non-oxidizing atmosphere, for example, under an inert gas atmosphere such as a helium or argon atmosphere; or under a reduced-pressure atmosphere. By cooling the melt of the metals that is obtained by the above method, an alloy represented by the compositional formula above can be formed. Furthermore, by conducting a heat treatment to the resulting alloy, if necessary, a more homogeneous alloy can be obtained, thereby enhancing its capability as a thermoelectric conversion material. In this case, the conditions for the heat treatment are not particularly limited. Although it depends on the types, amounts, etc., of the metallic elements contained, the heat treatment is preferably conducted at a temperature in the range of about 1450 to 1900° C. In order to prevent the oxidation of the metal material, the heat treatment, is preferably conducted under a non-oxidizing atmosphere, such as when melting is performed.

When the alloy obtained by the aforementioned method is used for a specific application, such as for a thermoelectric conversion material, the alloy is generally used in the form of a sintered body suitable for the target application. In the process of preparing a sintered body, an alloy represented by the compositional formula above is first, pulverized into fine powder, and then molded into a desirable shape. The degree of pulverization (particle size, particle size distribution, particle shape, etc.) is not particularly limited; however, by making the powder as small as possible, the subsequent step (i.e., sintering) becomes easier. For example, by using a ball mill or like pulverization means, pulverization and mixing of the alloy can be simultaneously conducted. The method for sintering the pulverized material is not particularly limited, and any heating means, such as an electric heating furnace or a gas heating furnace, which is generally used, may be employed. The heating temperature and heating time are also not particularly limited, and these conditions may be suitably selected so as to form a sintered body having sufficient strength. In particular, the use of electric current sintering allows a precise sintered body to be obtained in a short time. The electric current sintering is performed by placing a pulverized raw material in a mold having conductivity, pressing the material, and then sintering it by applying a pulsed direct current to the mold. The conditions for electric current sintering are also not particularly limited; for example, it may be performed under the application of a pressure, if necessary, of about 5 to 30 MPa, and heating at a temperature of about 600 to 850° C. for about 5 to 30 minutes. In order to prevent the oxidation of the metal material, the heating is preferably conducted under a non-oxidizing atmosphere, for example, under a nitrogen, argon, or like inert gas atmosphere; a reducing atmosphere; or a reduced-pressure atmosphere.

The above method allows a sintered body of metal material comprising an alloy represented by compositional formula Mn₃₋ₓM¹ₓSi_{y}Al_{z}M²ₐ to be obtained, wherein M¹ is at least one element selected from the group consisting of Ti, V, Cr, Fe, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a≦1.

The metal material of the present invention obtained by the above method has a negative Seebeck coefficient at. a temperature in the range of 25 to 700° C.; and has a high negative Seebeck coefficient at a temperature of 600° C. or below, in particular, in the range of about 300 to 500° C. The metal material exhibits a very low electric resistivity of 1 mΩ·cm or less in the temperature range of 25 to 700° C. Accordingly, the metal material exhibits excellent thermoelectric conversion capability as an n-type thermoelectric conversion material in the aforementioned temperature range. Furthermore, the metal material has excellent heat resistance, oxidation resistance, etc. For example, it is almost free from deterioration in thermoelectric conversion capability, even when used for a long period of time in the temperature range of about 25 to 700° C.

Utilizing the above characteristics, the metal material of the present invention can be efficiently used, for example, as an n-type thermoelectric conversion material that is usable in the air in a temperature range of room temperature to about 600° C., and preferably about 300 to 500° C.

FIG. 1 schematically shows one example of a thermoelectric generation module that uses a thermoelectric conversion material formed of a sintered body of the metal material of the present invention as an n-type thermoelectric conversion element. The structure of the thermoelectric generation module is the same as that of a known thermoelectric generation module. More specifically, the thermoelectric generation module comprises a substrate material, a p-type thermoelectric conversion material, an n-type thermoelectric conversion material, electrodes, etc., wherein the metal material of the present invention is used as an n-type thermoelectric conversion material.

### Advantageous Effects of Invention

The metal material of the present invention has a negative Seebeck coefficient and low electric resistivity, and further exhibits excellent heat resistance, oxidation resistance, etc.

Utilizing the above characteristics, the metal material can be effectively used as an n-type thermoelectric conversion material that exhibits excellent performance in a temperature range of room temperature to about 600° C., even in air under which it has been difficult to use conventional materials for a long period of time. Accordingly, by incorporating into a system a sintered body made of the metal material as an n-type thermoelectric conversion element for the thermoelectric generation module, it becomes possible to efficiently use the thermal energy that used to be released into atmosphere.

### BRIEF DESCRIPTION OF DRAWINGS

FIG. 1 is a schematic diagram illustrating a thermoelectric generation module that uses a sintered body of the metal material of the present invention as an n-type thermoelectric conversion material.

FIG. 2 is a graph showing the temperature dependencies of the Seebeck coefficients of the sintered bodies of a metal material obtained in Examples 1 to 3 measured in the air at 25 to 700° C.

FIG. 3 is a graph showing the temperature dependencies of the electric resistivity of the sintered bodies of a metal material obtained in Examples 1 to 3 measured in the air at 25 to 700° C.

FIG. 4 is a graph showing the temperature dependency of the thermal conductivity of the sintered body of a metal material obtained in Example 1 measured in the air at 25 to 700° C.

FIG. 5 is a graph showing the temperature dependency of the dimensionless figure of merit (ST) of the sintered body of a metal material obtained in Example 1 measured in the air at 25 to 700° C.

### DESCRIPTION OF EMBODIMENTS

The present invention is explained in detail with reference to the Examples.

### Example 1

Using manganese (Mn) as a source of Mn, silicon (Si) as a source of Si, and aluminum (Al) as a source of Al, the raw materials were mixed such that Mn:Si:Al (elemental ratio)=3.0:4.0:3.0. The raw material mixture was melted by an arc-melting method under an argon atmosphere; the melt was then fully mixed, and cooled to room temperature to obtain an alloy comprising the metal components mentioned above.

Subsequently, the resulting alloy was subjected to ball mill pulverization using an agate vessel and an agate ball. Thereafter, the resulting powder was pressed into a disc shape having a diameter of 40 mm and a thickness of 4.5 mm. The result was placed in a carbon mold, heated to 850° C. by applying a pulsed current of about 2700 A (pulse width: 2.5 milliseconds, frequency: 29 Hz), and maintained at the temperature for 15 minutes. After performing electric current sintering, the application of current and pressure was stopped, and the result was allowed to cool to obtain a sintered body.

### Examples 2 to 10

The sintered bodies having the compositions shown in Table 1 were obtained in the same manner as in Example 1, except that the types and proportions of the raw materials were altered. As the raw materials, elementary metals of each material were used.

### Test Example

The Seebeck coefficient, electric potential resistibility, thermal conductivity, and dimensionless figure of merit of each sintered body of Examples 1 to 37 were obtained by the methods described below.

Hereunder, the method for obtaining the physical-property values to evaluate the thermoelectrical characteristics is explained. The Seebeck coefficient and electric resistivity were measured in the air, and the thermal conductivity was measured in the vacuum.

### Seebeck Coefficient

A sample was molded into a rectangular column having a cross-section of about 3 to 5 mm square and a length of about 3 to 8 mm. An R-type thermocouple (platinum-platinum-rhodium) was attached to each end of the sample using a silver paste. The sample was placed in a tubular electric furnace, heated to 100 to 700° C., and given a temperature difference by applying room temperature air using an air pump to one of the ends provided with the thermocouple. Thereafter, the thermoelectromotive forces generated between both ends of the sample were measured using the platinum wires of the thermocouples. The Seebeck coefficient was calculated based on the thermoelectromotive force and the temperature difference between the ends of the sample.

### Electric Resistivity

A sample was molded into a rectangular column having a cross-section of about 3 to 5 mm square and a length of about 3 to 8 mm. Using a silver paste and a platinum wire, electric current terminals were provided at both ends, and voltage terminals were provided at the side surfaces. The electric resistivity was measured by a DC four-terminal method.

### Thermal Conductivity

A sample was molded into a shape having a width of about 5 mm, a length of about 8 mm, and a thickness of about 1.5 mm. The thermal diffusivity and specific heat were measured by a laser flash method. The thermal conductivity was calculated by multiplying the resulting values by density measured using Archimedes' method.

Table 1 shows the Seebeck coefficient (μV/K), electric resistivity (mΩ·cm), thermal conductivity (W/m·K²), and dimensionless figure of merit, at 500° C. of each alloy obtained in each Example.

TABLE 1

| | | | | | Dimensionless |
|---|---|---|---|---|---|
| | | Seebeck coefficient at | Electric resistivity | Thermal conductivity | figure of merit |
| | | 500° C. | at 500° C. | at 500° C. | at 500° C. |
| No. | Composition | (μV/K) | (mΩ · cm) | (W/m · K²) | ZT |
| 1 | Mn₃Si₄Al₃ | −92.9 | 0.91 | 3.6 | 0.20 |
| 2 | Mn_{2.8}Co_{0.2}Si₄Al₃ | −48.4 | 0.99 | 3.4 | 0.05 |
| 3 | Mn_{2.5}Fe_{0.2}Si₄Al₃ | −41.8 | 0.80 | 3.5 | 0.05 |
| 4 | Mn_{2.5}Ni_{0.2}Si₄Al₃ | −10.1 | 0.60 | 3.3 | 0.004 |
| 5 | Mn₃Si_{4.5}Al₃ | −50.1 | 0.93 | 3.6 | 0.06 |
| 6 | Mn₃Si_{4.2}Al_{2.5} | −72.5 | 0.84 | 3.6 | 0.13 |
| 7 | Mn₃Si_{3.5}Al_{3.2} | −83.9 | 0.91 | 3.7 | 0.16 |
| 8 | Mn₃Si_{3.5}Al₃ | −84.1 | 1.0 | 3.2 | 0.17 |
| 10 | Mn₃Si_{3.9}Al₃ | −83.1 | 1.0 | 3.2 | 0.17 |
| 11 | Mn₃Si_{3.8}Al₃P_{0.2} | −66.2 | 0.7 | 3.0 | 0.16 |
| 12 | Mn₃Si₄Al₂P | −40.5 | 0.6 | 3.1 | 0.07 |
| 13 | Mn₃Si_{3.8}Al₃B_{0.2} | −82.3 | 0.8 | 2.9 | 0.23 |
| 14 | Mn₃Si₄Al₂B | −79.4 | 0.7 | 3.3 | 0.21 |
| 15 | Mn₃Si_{3.5}Al₃Ga_{0.2} | −80.1 | 0.9 | 3.0 | 0.18 |
| 16 | Mn₃Si₄Al₂Ga | −67.8 | 1.0 | 2.7 | 0.13 |
| 17 | Mn₃Si_{3.8}Al₃Ge_{0.2} | −54.3 | 0.7 | 3.5 | 0.09 |
| 18 | Mn₃Si₄Al₂Ge | −32.7 | 0.5 | 3.2 | 0.05 |
| 19 | Mn₃Si_{3.8}Al₃Sn_{3.2} | −68.5 | 0.6 | 3.7 | 0.16 |
| 20 | Mn₃Si₄Al₂Sn | −32.1 | 0.5 | 2.8 | 0.06 |
| 21 | Mn₃Si_{3.8}Al₃Bi_{0.2} | −72.9 | 0.8 | 3.2 | 0.16 |
| 22 | Mn₃Si₄Al₂Bi | −49.7 | 0.7 | 3.4 | 0.08 |
| 23 | Mn₃Si₄Al₃Bi_{0.02} | −82.8 | 0.9 | 3.3 | 0.18 |
| 24 | Mn_{2.9}Ti_{0.1}Si₄Al₃ | −92.1 | 0.9 | 3.5 | 0.21 |
| 25 | Ti₃Si₄Al₃ | −67.2 | 1.0 | 2.7 | 0.13 |
| 26 | Mn_{2.9}V_{0.1}Si₄Al₃ | −87.2 | 0.9 | 3.4 | 0.19 |
| 27 | V₃Si₄Al₃ | −88.3 | 1.0 | 3.8 | 0.16 |
| 28 | Mn_{2.9}Cr_{0.1}Si₄Al₃ | −70.5 | 0.8 | 3.2 | 0.15 |
| 29 | Cr₃Si₄Al₃ | −91.3 | 1.0 | 3.1 | 0.21 |
| 30 | Mn_{2.9}Fe_{0.1}Si₄Al₃ | −90.1 | 0.7 | 2.9 | 0.31 |
| 31 | Fe₃Si₄Al₃ | −89.5 | 1.0 | 3.0 | 0.21 |
| 32 | Mn_{2.9}Co_{0.1}Si₄Al₃ | −76.3 | 0.8 | 3.2 | 0.18 |
| 33 | Co₃Si₄Al₃ | −67.8 | 1.0 | 2.9 | 0.12 |
| 34 | Mn_{2.9}Ni_{0.1}Si₄Al₃ | −72.3 | 0.9 | 3.1 | 0.14 |
| 35 | Ni₃Si₄Al₃ | −65.5 | 1.0 | 3.2 | 0.10 |
| 36 | Mn_{2.9}Cu_{0.1}Si₄Al₃ | −82.1 | 0.9 | 3.3 | 0.18 |
| 37 | Cu₃Si₄Al₃ | −60.2 | 0.7 | 3.6 | 0.11 |

As is evident from the results described above, the sintered alloy bodies obtained in Examples 1 to 37 had a negative Seebeck coefficient and a low electric resistivity at 500° C., therefore having an excellent capability as an n-type thermoelectric conversion material.

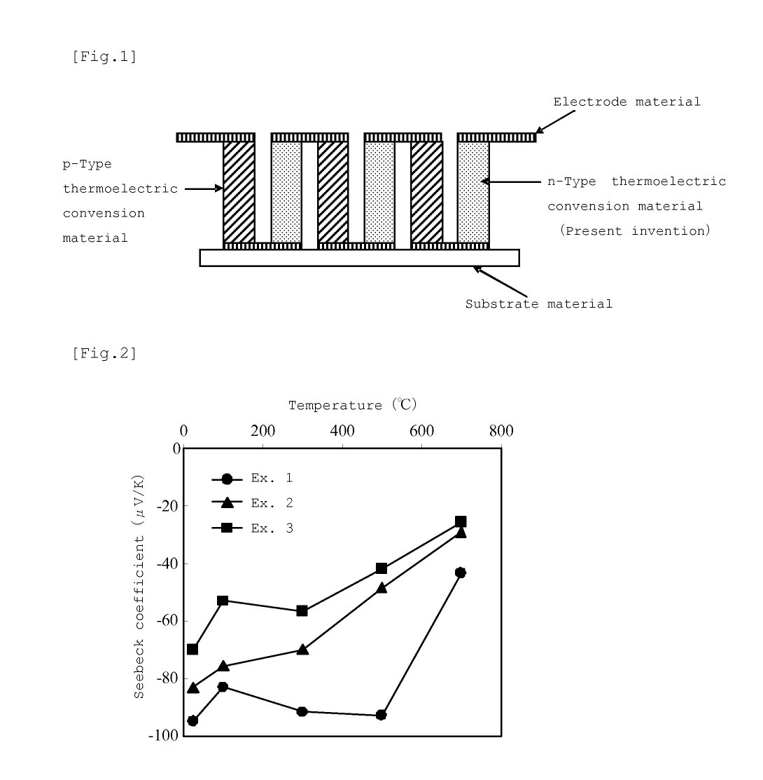

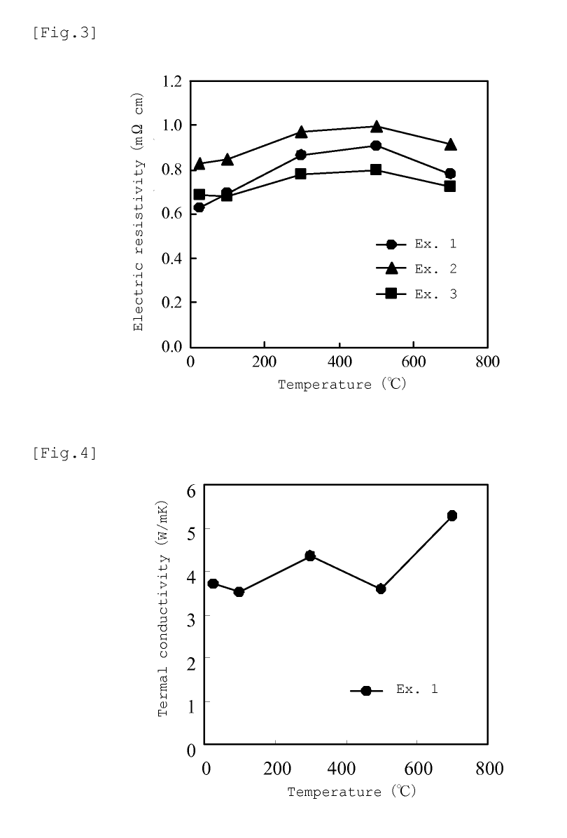

FIG. 2 is a graph showing the temperature dependencies of the Seebeck coefficients of the sintered alloy bodies obtained in Examples 1 to 3 measured in the air at 25 to 700° C. FIG. 3 is a graph showing the temperature dependencies of the electric resistivity of the sintered alloy bodies measured in the air at 25 to 700° C.

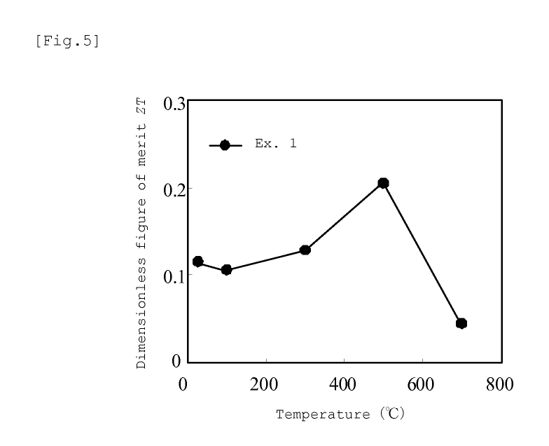

FIG. 4 shows the temperature dependency of the thermal conductivity of the sintered alloy body obtained in Example 1 measured in the air at 25 to 700° C. FIG. 5 shows the temperature dependency of the dimensionless figure of merit (ZT) of the sintered alloy body measured in the air at 25 to 700° C.

As is evident from the results described above, the sintered alloy bodies obtained in Examples 1 to 3 had a negative Seebeck coefficient in the temperature range of 25 to 700° C. They were confirmed to be n-type thermoelectric conversion materials in which the hot side has a high electric potential. These alloys had a high absolute value of the Seebeck coefficient in the temperature range of 600° C. or below, in particular about 300 to 500° C.

Furthermore, because no deterioration in performance due to oxidation was observed even in the measurement conducted in the air, it is revealed that the metal material of the present invention has an excellent oxidation resistance. Furthermore, the sintered alloy bodies obtained in Examples 1 to 3 had an electric resistivity (ρ) of less than 1 mΩ·cm in the temperature range of 25 to 700° C., revealing extremely excellent electrical conductivity. Accordingly, the sintered alloy bodies obtained in the Examples described above can be efficiently used as an n-type thermoelectric conversion material in the air in the temperature range up to about 600° C., in particular about 300 to 500° C.

1. A metal material comprising an alloy represented by compositional formula: Mn₃₋ₓM¹ₓSi_{y}Al_{z}M²ₐ,
wherein M¹ is at least one element selected from the group consisting of Ti, V, Cr, Fe, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a<1,
the alloy having a negative Seebeck coefficient at a temperature of 25° C. or higher.

2. A metal material comprising an alloy represented by compositional formula: Mn₃₋ₓM¹ₓSi_{y}Al_{z}M²ₐ,
wherein M¹ is at least one element selected from the group consisting of Ti, V, Cr, Fe, Co, Ni, and Cu; M² is at least one element selected from the group consisting of B, P, Ga, Ge, Sn, and Bi, where 0≦x≦3.0, 3.5≦y≦4.5, 2.5≦z≦3.5, and 0≦a≦1,
the alloy having an electrical resistivity of 1 mΩ·cm or less at a temperature of 25° C. or higher.

3. An n-type thermoelectric conversion material comprising the metal material of claim 1 or a sintered body thereof.

4. A thermoelectric conversion module comprising the n-type thermoelectric conversion material of claim 3.

5. An n-type thermoelectric conversion material comprising the metal material of claim 2 or a sintered body thereof.

6. A thermoelectric conversion module comprising the n-type thermoelectric conversion material of claim 5.
